(19) United States
(12) Patent Application Publication
(10) Pub. No.: US 2024/0052488 A1
(43) Pub. Date: Feb. 15, 2024

(54) FEEDING BLOCK AND SUBSTRATE PROCESSING APPARATUS INCLUDING THE SAME

(71) Applicant: WONIK IPS CO., LTD., Pyeongtaek-si Gyeonggi-do (KR)

(72) Inventors: Choong Hyun LEE, Pyeongtaek-si Gyeonggi-do (KR); Chong Hwan JONG, Pyeongtaek-si Gyeonggi-do (KR); Dong Bum KANG, Pyeongtaek-si Gyeonggi-do (KR)

(73) Assignee: WONIK IPS CO., LTD., Pyeongtaek-si Gyeonggi-do (KR)

(21) Appl. No.: 18/447,012

(22) Filed: Aug. 9, 2023

(30) Foreign Application Priority Data
Aug. 10, 2022 (KR) 10-2022-0099919

(51) Int. Cl. C23C 16/455

(52) U.S. Cl. CPC C23C 16/45559; B33Y 80/00

(57) ABSTRACT

Provided is a feeding block for transferring a process gas to a process chamber, the feeding block including a body, a first annular channel provided in the body, at least one first supply channel extending from an outer surface of the body to the first annular channel to supply a first process gas to the first annular channel, and at least one first discharge channel extending from the first annular channel to an outer surface of the body to discharge the first process gas in the first annular channel to an outside, wherein the body is provided as a single member such that the first supply channel, the first annular channel, and the first discharge channel have continuous inner surfaces.

### CROSS-REFERENCE TO RELATED PATENT APPLICATION

This application claims priority under 35 U.S.C. § 119(a) to Korean Patent Application No. 10-2022-0099919, filed on Aug. 10, 2022, in the Korean Intellectual Property Office, the disclosure of which is incorporated herein in its entirety by reference.

### BACKGROUND OF THE INVENTION

### 1. Field of the Invention

The present invention relates to a feeding block and a substrate processing apparatus including the same and, more particularly, to a feeding block for managing the uniformity of a gas supplied into a chamber of semiconductor manufacturing equipment, and a substrate processing apparatus including the same.

### 2. Description of the Related Art

In general, thin film deposition methods such as physical vapor deposition (PVD) using physical impact, e.g., sputtering, chemical vapor deposition (CVD) using chemical reaction, and atomic layer deposition (ALD) capable of depositing a very uniform micropattern of an atomic layer thickness and having excellent step coverage are used to deposit a thin film of a certain thickness on a semiconductor substrate.

Semiconductor devices manufactured using the above methods require patterns having a fine line width for high integration, and wafers require a large diameter to increase productivity of the semiconductor devices. As such, the uniformity of a process over the whole surface of the wafer is regarded as a critical issue.

Currently, the uniformity of a thin film deposition process has emerged as a critical issue in performing a double patterning technology (DPT) process, an ALD process, or the like on a large-diameter wafer.

### SUMMARY OF THE INVENTION

The present invention provides a feeding block capable of increasing the uniformity in a gas mixing block in a structure where channels of a cleaning gas, a source gas, and a reaction gas are independently provided, and a substrate processing apparatus including the same. However, the above description is merely an example, and the scope of the present invention is not limited thereto.

According to an aspect of the present invention, there is provided a feeding block for transferring a process gas to a process chamber, the feeding block including a body, a first annular channel provided in the body, at least one first supply channel extending from an outer surface of the body to the first annular channel to supply a first process gas to the first annular channel, and at least one first discharge channel extending from the first annular channel to an outer surface of the body to discharge the first process gas in the first annular channel to an outside, wherein the body is provided as a single member such that the first supply channel, the first annular channel, and the first discharge channel have continuous inner surfaces.

The first annular channel may be provided on a plane crossing a reference axis orthogonal to the outer surface in which the first discharge channel is provided.

A central axis of the first annular channel may be the same as the reference axis.

The first annular channel may have a circular shape in plan view.

The first discharge channel may include a plurality of first discharge channels provided along the first annular channel.

The first discharge channels may be provided at equal intervals along the first annular channel.

The feeding block may further include a second annular channel provided in the body to share a central axis of the first annular channel, a second supply channel extending from an outer surface of the body to the second annular channel to supply a second process gas to the second annular channel, and a second discharge channel extending from the second annular channel to an outer surface of the body to discharge the second process gas in the second annular channel to an outside, and the body may be provided as a single member such that the second supply channel, the second annular channel, and the second discharge channel have continuous inner surfaces.

The outer surface in which the first discharge channel is provided may be the same as the outer surface in which the second discharge channel is provided.

The first and second annular channels may be provided on planes crossing a reference axis orthogonal to the outer surface in which the first and second discharge channels are provided, and spaced apart from each other in a direction of the reference axis.

A central axis of each of the first and second annular channels may be the same as the reference axis, and a first distance from the reference axis to the first annular channel may be different from a second distance from the reference axis to the second annular channel.

A central axis of each of the first and second annular channels may be the same as the reference axis, and a first distance from the reference axis to the first annular channel may be the same as a second distance from the reference axis to the second annular channel.

The first discharge channel may be physically separate from the second annular channel, and the second discharge channel may be physically separate from the first annular channel.

The first and second annular channels may be provided on planes crossing a reference axis orthogonal to the outer surface in which the first and second discharge channels are provided, and the plane on which the first annular channel is provided may be the same as the plane on which the second annular channel is provided.

The second annular channel may have a circular shape in plan view.

The second discharge channel may include a plurality of second discharge channels provided along the second annular channel.

The second discharge channels may be provided at equal intervals along the second annular channel.

The first and second discharge channels may be provided in directions orthogonal to the outer surfaces in which the first and second discharge channels are provided.

The body may further include a through channel provided from an upper surface to a lower surface of the body in a direction orthogonal to the outer surfaces in which the first and second discharge channels are provided, and the first and second annular channels may have shapes surrounding the through channel.

The feeding block may be produced by three-dimensional (3D) printing.

According to another aspect of the present invention, there is provided a substrate processing apparatus including a process chamber having a processing space to process a substrate, a substrate supporter mounted in the processing space to seat the substrate on the substrate supporter, a gas ejector coupled to the process chamber to supply a process gas to the processing space, and the above-described feeding block provided on the gas ejector.

The substrate processing apparatus may further include a mixing block inserted between the feeding block and the gas ejector.

### BRIEF DESCRIPTION OF THE DRAWINGS

The above and other features and advantages of the present invention will become more apparent by describing in detail embodiments thereof with reference to the attached drawings in which:

FIG. 1 is a perspective view of a feeding block according to an embodiment of the present invention;

FIG. 2 is a perspective view of a lower portion of a feeding block cut along line C-C′ of FIG. 1;

FIG. 3 is a perspective view of a lower portion of a feeding block cut along line D-D′ of FIG. 1;

FIG. 4 is a cross-sectional view of a feeding block cut along line E-E′ of FIG. 1;

FIG. 5 is a see-through perspective view showing channels of a feeding block, according to an embodiment of the present invention;

FIGS. 6 to 8 are cross-sectional views showing the relationship between a first annular channel and a second annular channel, according to various embodiments of the present invention;

FIG. 9 is a cross-sectional view of a substrate processing apparatus according to another embodiment of the present invention; and

FIGS. 10 to 13 are tables comparatively showing substrate processing results using an existing feeding block and a feeding block of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

A feeding block 100 is a device for ejecting a first process gas into a processing space A provided in a process chamber to process a substrate S.

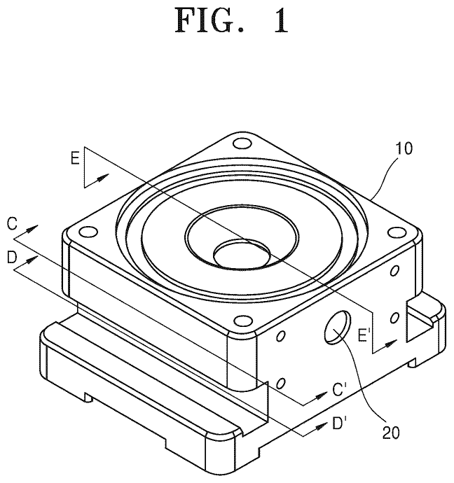

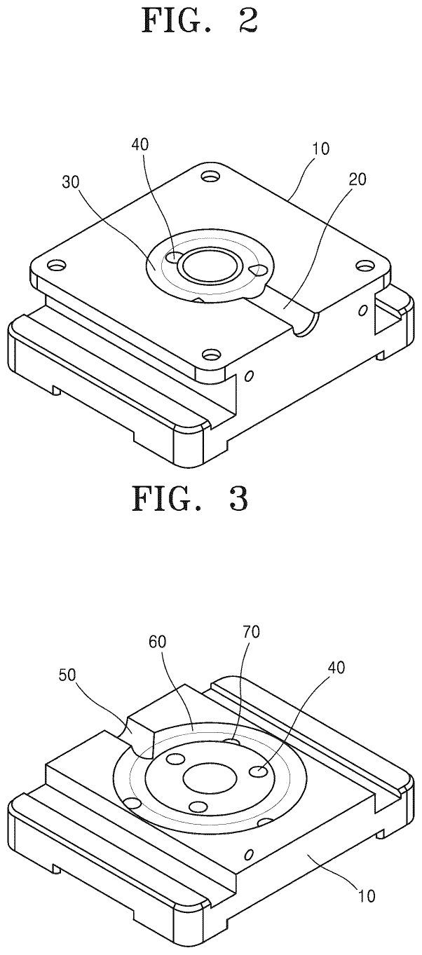

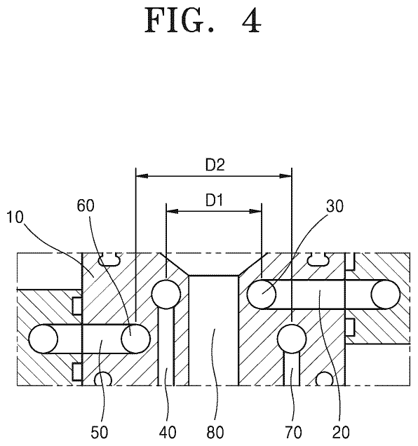

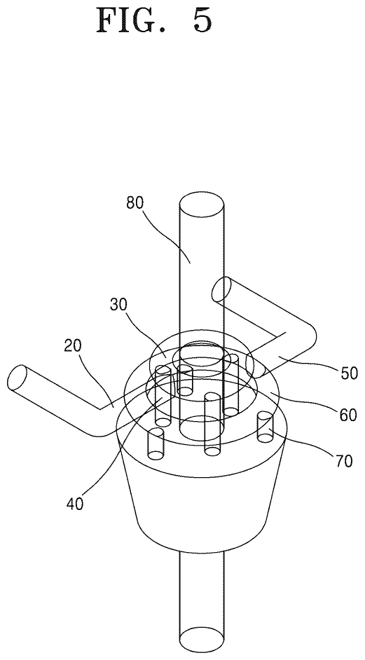

FIG. 1 is a perspective view of the feeding block 100 according to an embodiment of the present invention, FIGS. 2 and 3 are perspective views of lower portions of the feeding block 100 cut along lines C-C′ and D-D′ of FIG. 1, FIG. 4 is a cross-sectional view cut along line E-E′ of FIG. 1, and FIG. 5 is a see-through perspective view showing channels of the feeding block 100, according to an embodiment of the present invention.

Initially, as shown in FIGS. 1 and 2, the feeding block 100 according to an embodiment of the present invention may include a body 10, a first supply channel 20, a first annular channel 30, and a first discharge channel 40.

The body 10 may be provided in a substantially hexahedral shape, complicated channels through which the first process gas flows may be provided in the body 10, an opening through which the first process gas is introduced may be provided in an outer surface of the body 10, and another opening connected to the opening to expel the first process gas may be provided in an outer surface of the body 10.

A lower coupling surface couplable to an apparatus for receiving the first process gas may be provided on an outer surface of the body 10. Specifically, a sealing and coupling structure couplable to a shower head of a process chamber or a mixing block for mixing the first process gas may be provided on a lower surface of the body 10.

The body 10 is not limited to the hexahedral shape and may have various shapes through which the first process gas is introduced and expelled and which have at least one surface couplable to the apparatus for receiving the first process gas.

The first process gas may include a source gas and a reaction gas.

As shown in FIG. 2, the first supply channel 20 may be provided as a channel extending from a side surface to the inside of the body 10 to introduce the first process gas into the body 10. Specifically, the first supply channel 20 may be provided horizontally and linearly from the side surface of the body 10 to the first annular channel 30 to be described below. However, when an additional structure is provided in the body 10, the first supply channel 20 may include a bypass connected to the first annular channel 30.

The first process gas may include a source gas supplied from a source gas supplier 600 or a reaction gas supplied from a reaction gas supplier 700.

The first supply channel 20 may be provided as a channel penetrating from an opening in an outer surface of the body 10 to a center of the body 10, such that the first process gas introduced through the opening in the outer surface of the body 10 may flow from the opening to the center.

As shown in FIG. 2, the first annular channel 30 may include a channel provided on a plane crossing a reference axis orthogonal to an outer surface in which the first discharge channel 40 is provided.

For example, the first annular channel 30 may be provided in the body 10 as a channel connected to the first supply channel 20, surrounding the reference axis corresponding to the center of the body 10, and having a circular shape on a plane.

Specifically, as shown in FIGS. 4 and 5, the first annular channel 30 may be provided as a doughnut-shaped channel surrounding the center in the body 10 and connected to the first supply channel 20, such that the first process gas flowing from the first supply channel 20 may flow along the first annular channel 30 around the center.

The first annular channel 30 may be provided parallel to a discharge surface provided on the lower surface of the body 10. That is, the first annular channel 30 may be provided parallel to the first discharge channel 40 to be described below, such that distances from portions of the first annular channel 30 to the discharge surface may be equal and the first process gas may be uniformly expelled.

As shown in FIG. 2, the first discharge channel 40 may include a channel extending from the first annular channel 30 to an outer surface of the body 10 to discharge the first process gas in the first annular channel 30 to the outside of the body 10.

Specifically, as shown in FIGS. 4 and 5, the first discharge channel 40 may be provided as a channel connected from the first annular channel 30 in the body 10 to the lower surface of the body 10 to provide the first process gas to the process chamber, such that the first process gas flowing in the first annular channel 30 may flow through the lower surface of the body 10 to the apparatus coupled to the outside of the feeding block 100.

The first discharge channel 40 may include a plurality of first discharge channels 40 provided in the ring-shaped first annular channel 30 and provided at equal intervals along the first annular channel 30.

For example, the first discharge channels 40 may be provided as channels extending downward from three equiangular points of the first annular channel 30 as shown in FIG. 2 and extending to the lower surface of the body 10 as shown in FIG. 5.

As such, the first process gas introduced through the first supply channel 20 may flow along the first annular channel 30 and be uniformly expelled downward from the body 10 through the plurality of first discharge channels 40.

The body 10 may be provided as a single part such that the first supply channel 20, the first annular channel 30, and the first discharge channel 40 have continuous inner surfaces without parting lines.

Specifically, the body 10 is a structure provided as a single member to have a continuous surface, and the parting lines for forming channels are not provided between the inner surfaces of the first supply channel 20, the first annular channel 30, and the first discharge channel 40.

For example, when the body 10 includes a plurality of parts coupled to form internal channels, the parting lines and micropores along the parting lines may be formed between the internal channels due to the coupling and thus the flow of the source gas or the reaction gas may not be uniform. However, by providing the body 10 as a single structure, the parting lines may not be formed, leakage of the gas may be prevented, and uniform and seamless flow of the gas may be achieved.

The body 10 may be produced by cast molding or injection molding, and more specifically, by three-dimensional (3D) printing.

For example, the body 10 may be produced by 3D printing and a plurality of surface cleaning processes may be performed to suppress surface particles. The plurality of cleaning processes may include primary cleaning (e.g., chemical cleaning), secondary cleaning (e.g., acid cleaning), and tertiary cleaning (e.g., abrasive flow machining (AFM)).

The feeding block 100 according to an embodiment of the present invention may further include a second supply channel 50, a second annular channel 60, and a second discharge channel 70.

The second supply channel 50 may be provided as a channel extending from a side surface to the inside of the body 10 in a direction corresponding to the first supply channel 20 to introduce a second process gas into the body 10. Specifically, the second supply channel 50 may be provided horizontally and linearly from the side surface of the body 10 to the second annular channel 60. However, when another structure in the body 10 interferes, the second supply channel 50 may include a bypass connected to the second annular channel 60.

The second process gas may include the source gas supplied from the source gas supplier 600 or the reaction gas supplied from the reaction gas supplier 700.

The second supply channel 50 may be provided as a channel penetrating from an opening in an outer surface of the body 10 to the center of the body 10, such that the second process gas introduced through the opening in the outer surface of the body 10 may flow from the opening to the center.

The second annular channel 60 may be provided to share a central axis with the first annular channel 30 in the body 10. For example, the second annular channel 60 may be provided in the body 10 as a channel connected to the second supply channel 50, surrounding the center of the body 10, and having a circular shape on a plane.

Specifically, as shown in FIGS. 4 and 5, the second annular channel 60 may be provided as a doughnut-shaped channel surrounding the center in the body 10 and connected to the second supply channel 50, such that the second process gas flowing from the second supply channel 50 may flow along the second annular channel 60 around the center.

The second discharge channel 70 may include a channel extending from the second annular channel 60 to an outer surface of the body 10 to discharge the second process gas in the second annular channel 60 to the outside of the body 10.

Specifically, as shown in FIGS. 4 and 5, the second discharge channel 70 may be provided as a channel connected from the second annular channel 60 in the body 10 to the lower surface of the body 10 to provide the second process gas to the process chamber, such that the second process gas flowing in the second annular channel 60 may flow through the lower surface of the body 10 to the apparatus coupled to the outside of the feeding block 100.

The second discharge channel 70 may include a plurality of second discharge channels 70 provided in the ring-shaped second annular channel 60 and provided at equal intervals along the second annular channel 60.

For example, the second discharge channels 70 may be provided as channels extending downward from three equiangular points of the second annular channel 60 as shown in FIG. 3 and extending to the lower surface of the body 10 as shown in FIG. 5.

As such, the second process gas introduced through the second supply channel 50 may flow along the second annular channel 60 and be uniformly expelled downward from the body 10 through the plurality of second discharge channels 70.

In this case, the source gas may flow through the first supply channel 20, the first annular channel 30, and the first discharge channel 40, and the reaction gas may flow through the second supply channel 50, the second annular channel 60, and the second discharge channel 70.

The outer surface in which the first discharge channel 40 is provided may be the same as the outer surface in which the second discharge channel 70 is provided. That is, the first and second discharge channels 40 and 70 may be provided in the same outer surface of the body 10, and more specifically, in the lower surface of the body 10.

The first annular channel 30 may be provided higher than the second annular channel 60.

That is, a channel in which the source gas flows may be provided at a higher position than a channel in which the reaction gas flows.

The second annular channel 60 may be provided parallel to the first annular channel 30.

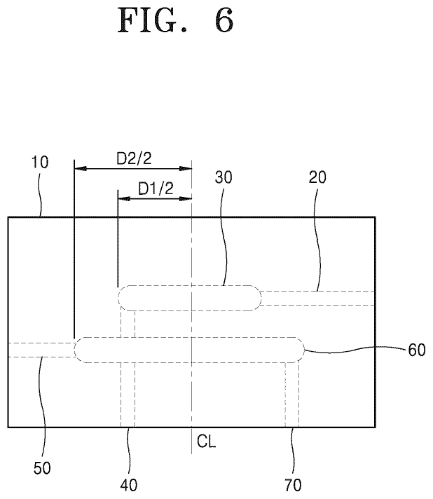

The second annular channel 60 may be provided to share the central axis of the first annular channel 30. Specifically, as shown in FIGS. 6 to 8, the first and second annular channels 30 and 60 may be provided around the same central axis such that the first and second process gases may be radially and uniformly expelled downward from the first and second annular channels 30 and 60 based on the central axis.

As shown in FIG. 4, a diameter D1 of a ring shape formed by the first annular channel 30 may be different from a diameter D2 of a ring shape formed by the second annular channel 60.

For example, the first annular channel 30 may be provided with the diameter D1 to surround the center, and the second annular channel 60 may be provided with the diameter D2 to surround the first annular channel 30 at a height different from that of the first annular channel 30. That is, the second annular channel 60 may be larger than the first annular channel 30.

As such, the first discharge channel 40 extending from the first annular channel 30 may be provided at one or more points of the diameter D1 of the first annular channel 30 in the outer surface of the body 10, and the second discharge channel 70 extending from the second annular channel 60 may be provided at one or more points of the diameter D2 of the second annular channel 60 in the outer surface of the body 10.

That is, the first discharge channel 40 may be provided closer to an axis of the lower surface of the body 10 than the second discharge channel 70. In addition, because the source gas flows through the first discharge channel 40 and the reaction gas flows through the second discharge channel 70, the source gas may be expelled downward at a distance closer to the axis of the lower surface of the body 10 than the reaction gas.

The feeding block 100 according to an embodiment of the present invention may further include a through channel 80.

The through channel 80 may be provided as a vertical channel penetrating through a center of a ring shape formed by the first annular channel 30 from an upper surface to the lower surface of the body 10, such that a cleaning gas having passed through a region of plasma generated by a plasma generator 800 may pass from the top to the bottom of the body 10.

The through channel 80 may include a channel penetrating through the center from the upper surface to the lower surface of the body 10, such that the cleaning gas may flow from the top of the body 10 to the mixing block coupled to the bottom of the body 10. That is, the through channel 80 is a channel through which the plasma flows to supply the cleaning gas to the process chamber from the outside of the process chamber.

The plasma generator 800 may include a remote plasma generator for generating plasma outside a chamber.

FIGS. 6 to 8 are cross-sectional views showing the relationship between the first and second annular channels 30 and 60, according to various embodiments of the present invention.

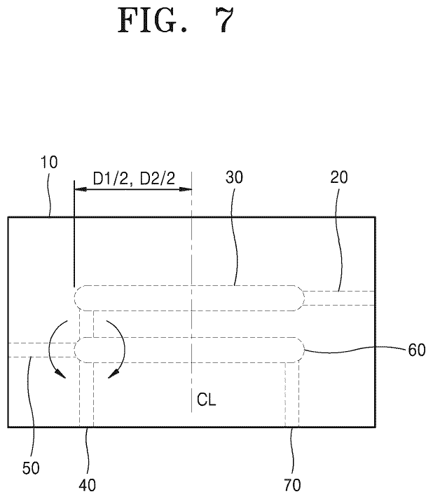

As shown in FIGS. 6 and 7, the first and second annular channels 30 and 60 may be provided on planes crossing a reference axis CL orthogonal to the outer surface in which the first and second discharge channels 40 and 70 are provided, and spaced apart from each other in a direction of the reference axis CL.

In this case, as shown in FIG. 6, a central axis CL of each of the first and second annular channels 30 and 60 may be the same as the reference axis CL, and a first distance D1/2 from the reference axis CL to the first annular channel 30 may be different from a second distance D2/2 from the reference axis CL to the second annular channel 60. The configuration and effect thereof are the same as those described above.

As shown in FIG. 7, the central axis CL of each of the first and second annular channels 30 and 60 may be the same as the reference axis CL, and the first distance D1/2 from the reference axis CL to the first annular channel 30 may be the same as the second distance D2/2 from the reference axis CL to the second annular channel 60.

For example, the first and second annular channels 30 and 60 may be provided with the same diameter at different heights. In this case, the first discharge channel 40 may be physically separate from the second annular channel 60. For example, the first discharge channel 40 may bypass the second annular channel 60 to expel the first process gas.

Because the first and second annular channels 30 and 60 are provided with the same diameter, amounts of the first and second process gases supplied to the first and second annular channels 30 and 60 may be the same and thus the first and second process gases may be uniformly expelled downward from the feeding block 100 through the first and second annular channels 30 and 60.

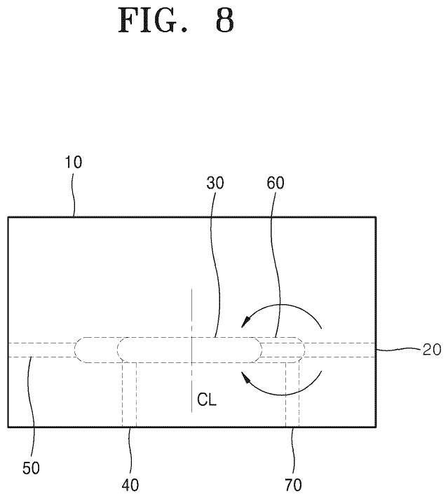

As shown in FIG. 8, the first and second annular channels 30 and 60 may be provided on planes crossing the reference axis CL orthogonal to the outer surface in which the first and second discharge channels 40 and 70 are provided, and the plane on which the first annular channel 30 is provided may be the same as the plane on which the second annular channel 60 is provided.

That is, the first and second annular channels 30 and 60 may be provided with different diameters at the same height.

For example, the first and second annular channels 30 and 60 may be provided at the same height and the first annular channel 30 may be provided closer to the reference axis CL than the second annular channel 60. In this case, the first supply channel 20 may be provided at the same height as the first annular channel 30 and bypass the second annular channel 60 to supply the first process gas, or provided at a different height parallel to the first annular channel 30 to supply the first process gas.

Because the first and second annular channels 30 and 60 are provided at the same height, distances from the first and second annular channels 30 and 60 to the bottom of the feeding block 100 may be the same and thus the first and second process gases may be uniformly expelled through the first and second annular channels 30 and 60.

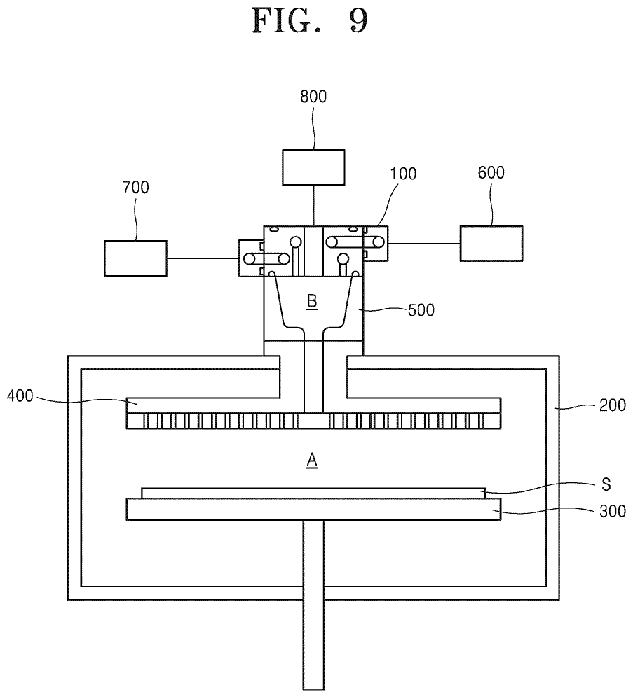

FIG. 9 is a cross-sectional view of a substrate processing apparatus according to another embodiment of the present invention.

The substrate processing apparatus according to another embodiment of the present invention may include a process chamber 200, a substrate supporter 300, a shower head 400, and the feeding block 100.

As shown in FIG. 9, the process chamber 200 may have the processing space A therein to process the substrate S.

The process chamber 200 may be a process chamber having the processing space A where the substrate S is processed. Specifically, the process chamber 200 may have therein the processing space A provided in a circular or rectangular shape to deposit a thin film on or etch a thin film deposited on the substrate S seated in and supported by a pocket of the substrate supporter 300 mounted in the processing space A.

A plurality of exhaust ports may be mounted at a lower side of the process chamber 200 to surround the substrate supporter 300. The exhaust ports may be connected through pipes to a vacuum pump mounted outside the process chamber 200 to suck air inside the processing space A of the process chamber 200, thereby exhausting various process gases from the processing space A or forming a vacuum atmosphere in the processing space A.

A gate serving as a passage through which the substrate S is loaded into or unloaded from the processing space A may be provided on a side surface of the process chamber 200.

The substrate supporter 300 may be mounted in the processing space A to seat the substrate S thereon.

The substrate supporter 300 may be included in the processing space A of the process chamber 200 to support the substrate S, and mounted to be rotatable about a rotation axis which is the same as a central axis of the process chamber 200.

The substrate supporter 300 may be provided in a disc shape so as to be rotatably mounted in the processing space A of the process chamber 200. Specifically, the substrate supporter 300 may heat the substrate S to a process temperature for depositing a thin film on or etching a thin film deposited on the substrate S seated in the pocket, by using a lower heater heated to the process temperature to heat the substrate S seated in the pocket.

In this case, the substrate supporter 300 may include a plurality of pockets to process a plurality of substrates.

The shower head 400 may be coupled into the process chamber 200 to supply the source gas or the reaction gas onto the substrate supporter 300 in the processing space A.

The shower head 400 may be provided in an upper portion of the process chamber 200 to face the substrate supporter 300 to eject various process gases such as the source gas and the reaction gas toward the substrate supporter 300.

The feeding block 100 may be provided on the shower head 400.

The feeding block 100 may be provided on the shower head 400 to supply the source gas and the reaction gas to the shower head 400 through the first and second discharge channels 40 and 70, such that the source gas and the reaction gas introduced from the outside may be supplied to the shower head 400. However, preferably, a device capable of mixing the source gas and the reaction gas may be further provided between the feeding block 100 and the shower head 400.

The substrate processing apparatus according to another embodiment of the present invention may further include a mixing block 500.

The mixing block 500 may be provided under the feeding block 100 and have therein a mixing space B for mixing the source gas or the reaction gas flowing from the feeding block 100.

An upper surface of the mixing block 500 may be coupled to the bottom of the feeding block 100 so as to be connected to the first discharge channel 40, the second discharge channel 70, and the through channel 80, and a lower surface of the mixing block 500 may be coupled to the shower head 400 on top of the process chamber 200.

The mixing block 500 may have the mixing space B to mix the source gas and the reaction gas before being supplied to the processing space A. For example, the source gas having passed through the first discharge channel 40 and the reaction gas having passed through the second discharge channel 70 are mixed while the flows thereof interfere with each other in the mixing space B.

As such, the conductance and flow aspects of the source gas and the reaction gas may be controlled and thus thickness uniformity of a thin film deposited on the substrate S may be increased.

The mixing block 500 may be produced by 3D printing.

In this case, the mixing block 500 may be produced by 3D printing and a plurality of surface cleaning processes may be performed to suppress surface particles. The plurality of cleaning processes may include primary cleaning (e.g., chemical cleaning), secondary cleaning (e.g., acid cleaning), and tertiary cleaning (e.g., AFM).

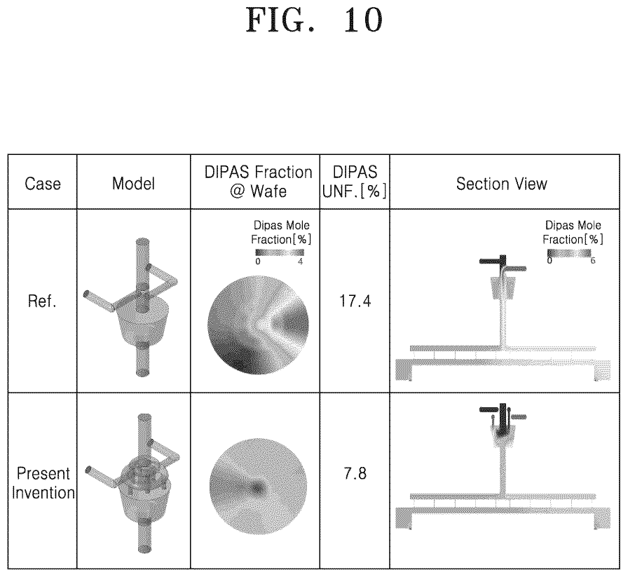

FIG. 10 is a table showing results of simulating di-isopropylamino silane (DIPAS) fractions on wafers processed using an existing feeding block and a feeding block of the present invention, and DIPAS fractions at cross-sections of the feeding blocks.

As shown in FIG. 10, the DIPAS fraction at the cross-section of the existing feeding block shows that the source gas is biased to the right on the drawing and thus the DIPAS fraction on the wafer is also biased to the right on the drawing.

On the other hand, the DIPAS fraction at the cross-section of the feeding block of the present invention shows that the source gas flows along the wall of the feeding block and the DIPAS fraction on the wafer is relatively uniform.

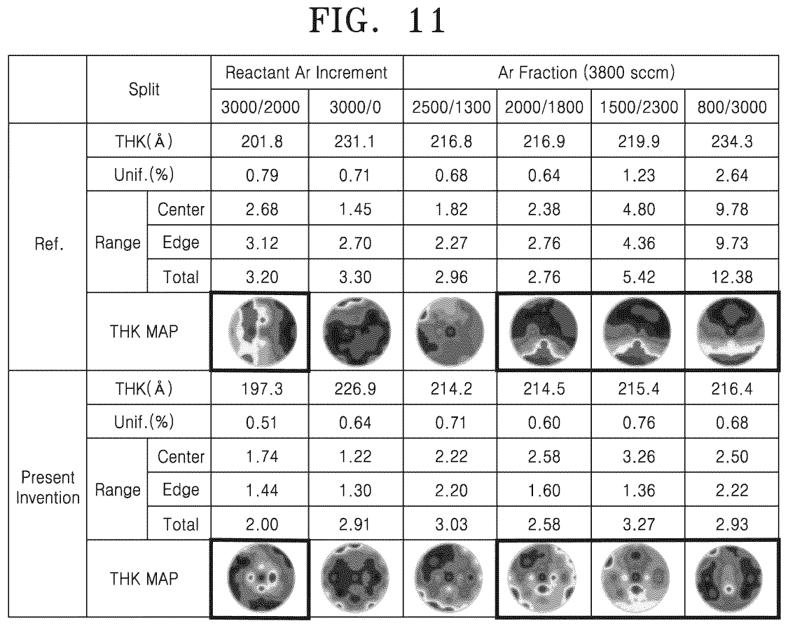

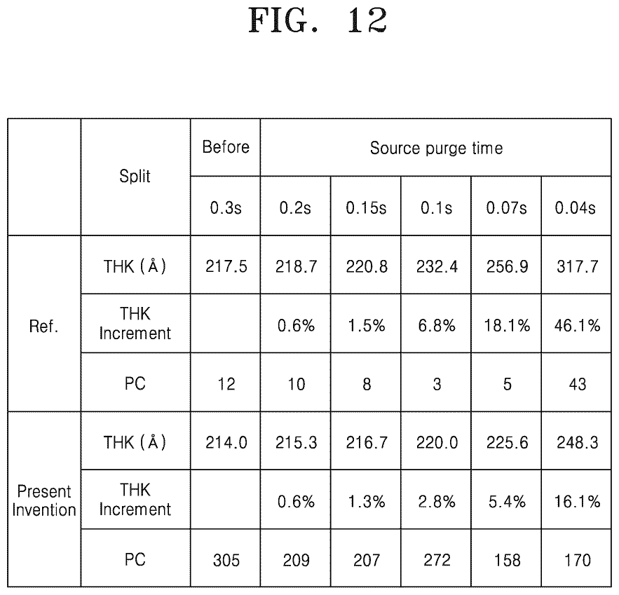

FIG. 11 is a table showing results of evaluating thickness maps on substrates processed using an existing feeding block and a feeding block of the present invention.

As shown in FIG. 11, the existing feeding block shows a non-uniform thickness map when argon (Ar) for a reactant line is 3000/2000 compared to a case in which Ar for the reactant line is 3000/0, and shows a thickness uniformity of 0.64 and a total range of 2.76 for an Ar fraction of 2000/1800, a thickness uniformity of 1.23 and a total range of 5.42 for an Ar fraction of 1500/2300, and a thickness uniformity of 2.64 and a total range of 12.38 for an Ar fraction of 800/3000, which are very non-uniform as shown on the thickness map.

On the other hand, the feeding block of the present invention shows uniform differences on the thickness map when Ar for the reactant line is 3000/0 and 3000/2000, and shows uniform thickness uniformities, total ranges, and thickness maps when the Ar fraction is 2500/1300, 2000/1800, 1500/2300, and 800/3000.

That is, the existing feeding block shows a seriously biased map when Ar for the reactant line is increased or when the Ar fraction is changed, but the feeding block of the present invention may maintain a concentric map even when the Ar ratio or the Ar fraction is changed.

Therefore, the feeding block according to the present invention has a high gas stability and may control the thickness by easily adjusting parameter splits for uniform fine tuning in a wide gas range.

FIG. 12 is a table showing results of evaluating thickness increments of substrates processed using an existing feeding block and a feeding block of the present invention.

As shown in FIG. 12, when a source purge time is changed from 0.3 s to 0.2 s, 0.15 s, 0.1 s, 0.07 s, and 0.04 s, the existing feeding block shows that a thickness increment is increased to 0.6%, 1.5%, 6.8%, 18.1%, and 46.1%.

On the other hand, when the source purge time is changed from 0.3 s to 0.2 s, 0.15 s, 0.1 s, 0.07 s, and 0.04 s, the feeding block of the present invention shows that the thickness increment is increased to 0.6%, 1.3%, 2.8%, 5.4%, and 16.1%, which are less than those of the existing feeding block.

That is, when the feeding block of the present invention is used, a better purge effect may be achieved compared to the existing feeding block, and deposition by chemical reaction may be suppressed due to an increase in source purge efficiency.

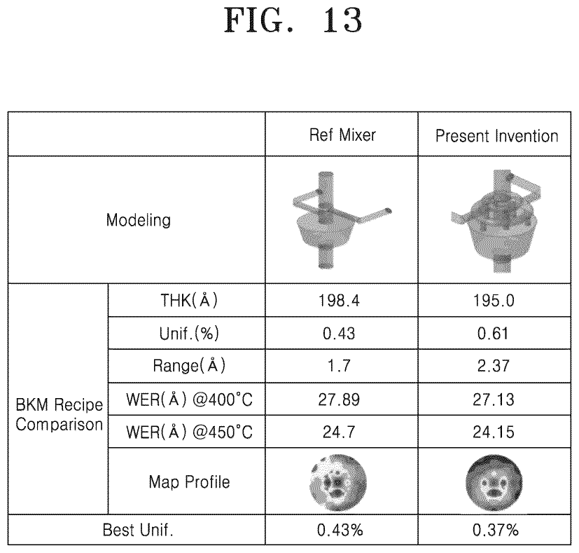

FIG. 13 is a table showing the influence of a manufacturing method on a map when substrates are processed with a best-known method (BKM) recipe by using an existing feeding block and a feeding block of the present invention.

As shown in FIG. 13, the existing feeding block shows the best uniformity of 0.43% and shows a map that sensitively changes according to a change in purge Ar ratio and a change in pressure.

On the other hand, the feeding block of the present invention shows the best uniformity of 0.37% and shows that gas mixing is improved and a concentric map is maintained in spite of a change in Ar ratio and a change in parameter.

That is, the feeding block and the substrate processing apparatus of the present invention may increase thickness uniformity of a deposited thin film, ensure a process margin because the uniformity of the deposited thin film may be maintained even when a process recipe is changed, and reduce a purge time to increase productivity.

Based on the above-described feeding block and substrate processing apparatus according to some embodiments of the present invention, thickness uniformity of a deposited thin film may be increased because a process gas is diffused by an annular channel provided in the feeding block and then is uniformly provided to a chamber through a plurality of discharge channels provided at equal intervals and connected to the annular channel, a process margin may be ensured because the uniformity of the deposited thin film may be maintained even when a process recipe is changed, and a purge time may be reduced to increase productivity. Furthermore, when heterogeneous gases are used, the process gas may be uniformly provided to the chamber by providing a plurality of annular channels in the feeding block and by using an additional mixing block to mix and offset the directionality of the process gas before being introduced into the chamber. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A feeding block for transferring a process gas to a process chamber, the feeding block comprising:
a body;
a first annular channel provided in the body;
at least one first supply channel extending from an outer surface of the body to the first annular channel to supply a first process gas to the first annular channel; and
at least one first discharge channel extending from the first annular channel to an outer surface of the body to discharge the first process gas in the first annular channel to an outside,
wherein the body is provided as a single member such that the first supply channel, the first annular channel, and the first discharge channel have continuous inner surfaces.

2. The feeding block of claim 1, wherein the first annular channel is provided on a plane crossing a reference axis orthogonal to the outer surface in which the first discharge channel is provided.

3. The feeding block of claim 2, wherein a central axis of the first annular channel is the same as the reference axis.

4. The feeding block of claim 1, wherein the first annular channel has a circular shape in plan view.

5. The feeding block of claim 1, wherein the first discharge channel comprises a plurality of first discharge channels provided along the first annular channel.

6. The feeding block of claim 5, wherein the first discharge channels are provided at equal intervals along the first annular channel.

7. The feeding block of claim 1, further comprising:
a second annular channel provided in the body to share a central axis of the first annular channel;
a second supply channel extending from an outer surface of the body to the second annular channel to supply a second process gas to the second annular channel; and
a second discharge channel extending from the second annular channel to an outer surface of the body to discharge the second process gas in the second annular channel to an outside,
wherein the body is provided as a single member such that the second supply channel, the second annular channel, and the second discharge channel have continuous inner surfaces.

8. The feeding block of claim 7, wherein the outer surface in which the first discharge channel is provided is the same as the outer surface in which the second discharge channel is provided.

9. The feeding block of claim 8, wherein the first and second annular channels are provided on planes crossing a reference axis orthogonal to the outer surface in which the first and second discharge channels are provided, and spaced apart from each other in a direction of the reference axis.

10. The feeding block of claim 9, wherein a central axis of each of the first and second annular channels is the same as the reference axis, and
wherein a first distance from the reference axis to the first annular channel is different from a second distance from the reference axis to the second annular channel.

11. The feeding block of claim 9, wherein a central axis of each of the first and second annular channels is the same as the reference axis, and
wherein a first distance from the reference axis to the first annular channel is the same as a second distance from the reference axis to the second annular channel.

12. The feeding block of claim 11, wherein the first discharge channel is physically separate from the second annular channel, and the second discharge channel is physically separate from the first annular channel.

13. The feeding block of claim 8, wherein the first and second annular channels are provided on planes crossing a reference axis orthogonal to the outer surface in which the first and second discharge channels are provided, and the plane on which the first annular channel is provided is the same as the plane on which the second annular channel is provided.

14. The feeding block of claim 7, wherein the second annular channel has a circular shape in plan view.

15. The feeding block of claim 7, wherein the second discharge channel comprises a plurality of second discharge channels provided along the second annular channel.

16. The feeding block of claim 15, wherein the second discharge channels are provided at equal intervals along the second annular channel.

17. The feeding block of claim 7, the first and second discharge channels are provided in directions orthogonal to the outer surfaces in which the first and second discharge channels are provided.

18. The feeding block of claim 7, wherein the body further comprises a through channel provided from an upper surface to a lower surface of the body in a direction orthogonal to the outer surfaces in which the first and second discharge channels are provided, and
wherein the first and second annular channels have shapes surrounding the through channel.

19. The feeding block of claim 1, wherein the feeding block is produced by three-dimensional (3D) printing.

20. A substrate processing apparatus comprising:
a process chamber having a processing space to process a substrate;
a substrate supporter mounted in the processing space to seat the substrate on the substrate supporter;
a gas ejector coupled to the process chamber to supply a process gas to the processing space; and
a feeding block for transferring a process gas to the process chamber,
wherein the feeding block is provided on the gas ejector and comprises,
a body;
a first annular channel provided in the body;
at least one first supply channel extending from an outer surface of the body to the first annular channel to supply a first process gas to the first annular channel; and
at least one first discharge channel extending from the first annular channel to an outer surface of the body to discharge the first process gas in the first annular channel to an outside,
wherein the body is provided as a single member such that the first supply channel, the first annular channel, and the first discharge channel have continuous inner surfaces.
